(19) United States
(12) Patent Application Publication
(10) Pub. No.: US 2010/0081251 A1
(43) Pub. Date: Apr. 1, 2010

(54) METHOD FOR MANUFACTURING SOI SUBSTRATE

(75) Inventors: Atsuo ISOBE, Isehara (JP); Junpei MOMO, Sagamihara (JP); Naoki OKUNO, Sagamihara (JP)

Correspondence Address: ERIC ROBINSON, PMB 955, 21010 SOUTHBANK ST., POTOMAC FALLS, VA, 20165, US

(73) Assignee: SEMICONDUCTOR ENERGY LABORATORY CO., LTD., Kanagawa-ken (JP)

(21) Appl. No.: 12/557,545

(22) Filed: Sep. 11, 2009

(30) Foreign Application Priority Data
Sep. 29, 2008 (JP) 2008-249992

(51) Int. Cl. H01L 21/762

(52) U.S. Cl. 438/458; 438/795; 257/E21.568

(57) ABSTRACT

A single crystal semiconductor substrate is irradiated with accelerated ions to form an embrittled region in the single crystal semiconductor substrate. The single crystal semiconductor substrate and a base substrate are bonded to each other with an insulating layer interposed therebetween. The single crystal semiconductor substrate is separated at the embrittled region to form a semiconductor layer over the base substrate. Heat treatment is performed to reduce defects in the semiconductor layer. The semiconductor layer is then irradiated with laser light.

### BACKGROUND OF THE INVENTION

1. Field of the Invention

The invention disclosed herein relates to a method for manufacturing a substrate in which a semiconductor layer is provided over an insulating layer, and particularly relates to a method for manufacturing a silicon-on-insulator (SOI) substrate. The invention also relates to a method for manufacturing a semiconductor device using the substrate.

2. Description of the Related Art

In recent years, integrated circuits formed using, instead of a bulk silicon wafer, a silicon-on-insulator (SOI) substrate where a thin single crystal semiconductor layer is present over an insulating surface have been researched. Because parasitic capacitance generated by a drain of a transistor and a substrate can be reduced by use of an SOI substrate, SOI substrates are attracting attention as substrates which improve performance of semiconductor integrated circuits.

One of known methods for manufacturing SOI substrates is a Smart Cut (registered trademark) method (for example, see Reference 1). A summary of a method for manufacturing an SOI substrate by a Smart Cut method is described below. First, hydrogen ions are implanted into a silicon wafer by an ion implantation method; thus, a microbubble layer is formed at a predetermined depth from the surface. Next, the silicon wafer into which hydrogen ions are implanted is bonded to another silicon wafer with a silicon oxide film interposed therebetween. After that, through heat treatment, part of the silicon wafer into which hydrogen ions are implanted is separated as a thin film at the microbubble layer. Accordingly, a single crystal silicon film is formed over the other silicon wafer.

A method for forming a single crystal silicon layer over a base substrate made of glass by using such a Smart Cut method as described above has been proposed (for example, see Reference 2). Glass substrates may have larger sizes and are less expensive than silicon wafers; thus, glass substrates are mainly used in manufacturing liquid crystal display devices. By using a glass substrate as a base substrate, a large-sized inexpensive SOI substrate can be manufactured.

Note that Reference 2 discloses a method for irradiating a single crystal silicon layer with laser light in order to improve crystal quality of the single crystal silicon layer.

### [Reference]

Reference 1: Japanese Published Patent Application No. H05-211128

Reference 2: Japanese Published Patent Application No. 2005-252244

### SUMMARY OF THE INVENTION

As disclosed in Reference 2, a single crystal semiconductor layer is irradiated with laser light, whereby the single crystal semiconductor layer is melted and the crystallinity thereof can be improved even in the case of using a glass substrate having low heat resistance or the like.

In order to improve semiconductor characteristics by laser light irradiation, it is necessary to achieve partial melting of a semiconductor layer by laser light irradiation. This is because it is necessary to leave a portion which serves as a seed for regrowth of single crystal. Note that “partial melting” mentioned above means melting a semiconductor layer by laser light irradiation to a depth smaller than the depth to a base side interface (i.e., smaller than the thickness of the semiconductor layer). In other words, it refers to a state in which the upper portion of the semiconductor layer is melted into a liquid phase whereas the lower portion is not melted and remains in a solid phase.

In the case where a semiconductor layer is partially melted as described above, most of defects existing in the melted region are repaired, but defects in the non-melted region remain unrepaired. In addition, the effect of heat during partial melting leads to crystal defect concentration in the vicinity of a boundary between a melted region and a non-melted region. Such defects remaining in a non-melted region or in the vicinity of a boundary hinder the improvement in characteristics of finished semiconductor devices and thus cause problems.

In order to obtain sufficient characteristics of a single crystal semiconductor layer, it is necessary to irradiate the single crystal semiconductor layer with laser light having an optimal energy density at which the aforementioned non-melted region is made sufficiently small. However, there is temporal variation in energy density of laser light and thus it is difficult to perform laser light irradiation under constant conditions. Therefore, variation in energy density of laser light causes variation in characteristics of an SOI substrate, and this leads to a problem of variation in characteristics of a finished semiconductor device.

In view of the above problems, it is an object of an embodiment of the disclosed invention to provide an SOI substrate having sufficient characteristics in the case of performing laser light irradiation. It is another object to reduce variation in characteristics of an SOI substrate resulting from laser light irradiation conditions.

In the disclosed invention, a combination of relatively low temperature heat treatment and subsequent laser irradiation treatment is employed. More specific methods for achieving the objects are as follows.

A feature of an embodiment of the disclosed invention is to irradiate a single crystal semiconductor substrate with accelerated ions to form an embrittled region in the single crystal semiconductor substrate, to bond the single crystal semiconductor substrate and a base substrate to each other with an insulating layer interposed therebetween, to separate the single crystal semiconductor substrate at the embrittled region to form a semiconductor layer over the base substrate, to perform heat treatment to reduce defects in the semiconductor layer, and to irradiate the semiconductor layer with laser light.

In the above embodiment, the heat treatment can be performed after etching the semiconductor layer over the base substrate. By the heat treatment, the single crystal semiconductor substrate may be separated and defects in the semiconductor layer may be reduced. The laser light irradiation is preferably performed with light having an intensity at which the semiconductor layer is partially melted.

In the above embodiment, a glass substrate can be used as the base substrate. The heat treatment may be performed at a temperature higher than or equal to 680° C., preferably, higher than or equal to 700° C., and lower than a strain point of the base substrate. By the laser light irradiation, surface planarity of the semiconductor layer can be improved and defects in the semiconductor layer can be reduced.

It is preferable that a single crystal silicon substrate be used as the single crystal semiconductor substrate and the heat treatment be performed such that a Raman spectrum of the semiconductor layer after the heat treatment has a wavenumber of 520 cm⁻¹ to 521 cm⁻¹ at a peak and a full width at half maximum of 3.5 cm⁻¹ or less at the peak.

In this specification, the term “single crystal” means a crystal in which, when certain crystal axes are focused, the direction of the crystal axes is oriented in the same direction of the crystal axes in any portion of a sample and which has no crystal grain boundaries in the crystal. In this specification, the “single crystal” includes a crystal in which directions of crystal axes are uniform as described above and which has no grain boundary even when including a crystal defect or a dangling bond. In addition, “re-single-crystallization of a single crystal semiconductor layer” means that a semiconductor layer returns to have a single crystal structure through a different state from the single crystal structure (e.g., a liquid-phase state). In addition, it can be said that “re-single-crystallization of a single crystal semiconductor layer” means that a single crystal semiconductor layer is recrystallized to form a single crystal semiconductor layer.

The term “semiconductor device” in this specification refers to devices in general that can operate by utilizing semiconductor characteristics, and an electro-optical device, a semiconductor circuit, and a display device are all included in the semiconductor device.

The term “display device” in this specification includes a light emitting device and a liquid crystal display device. A light emitting device includes a light emitting element, and a liquid crystal display device includes a liquid crystal element. A light emitting element includes, in its scope, an element whose luminance is controlled by a current or a voltage, and specifically includes an inorganic electroluminescent (EL) element, an organic EL element, and the like.

In an embodiment of the disclosed invention, a semiconductor layer in which crystal defects have been sufficiently reduced in advance is irradiated with laser light; thus, an SOI substrate having sufficient characteristics can be obtained also in the case of partial melting by laser light irradiation. In addition, even if irradiation energy density of laser light is lowered, a semiconductor layer having equivalent characteristics can be obtained; thus, it is possible to reduce variation in characteristics of an SOI substrate resulting from variation in energy density of laser light.

### BRIEF DESCRIPTION OF THE DRAWINGS

FIGS. 1A to 1F are cross-sectional views illustrating an example of a method for manufacturing an SOI substrate.

FIGS. 2A and 2B are cross-sectional views illustrating an example of a method for manufacturing an SOI substrate.

FIGS. 3A to 3G are cross-sectional views illustrating an example of a method for manufacturing an SOI substrate.

FIGS. 4A to 4C are cross-sectional views illustrating an example of a method for manufacturing an SOI substrate.

FIGS. 5A to 5D are cross-sectional views illustrating an example of a method for manufacturing a transistor.

FIGS. 6A to 6D are cross-sectional views illustrating an example of a method for manufacturing a transistor.

FIGS. 7A and 7B are a plan view of a transistor and a cross-sectional view thereof, respectively.

FIGS. 8A to 8H illustrate electronic devices each including a semiconductor device.

FIGS. 9A to 9C illustrate an electronic device including a semiconductor device.

FIGS. 10A and 10B illustrate experimental results according to an example.

### DETAILED DESCRIPTION OF THE INVENTION

Embodiments will be hereinafter described with reference to the accompanying drawings. Note that the present invention is not limited to the description in the embodiments below, and it is apparent to those skilled in the art that modes and details of the present invention can be changed in various ways without departing from its spirit. In addition, structures according to different embodiments can be implemented in combination as appropriate. Note that in the structures of the invention described below, the same portions or portions having similar functions are denoted by the same reference numerals, and repetitive description thereof is omitted.

### Embodiment 1

In this embodiment, an example of a method for manufacturing a semiconductor substrate (an SOI substrate) will be described with reference to drawings. Specifically, the case of manufacturing a semiconductor substrate in which a single crystal semiconductor layer is provided over a base substrate will be described.

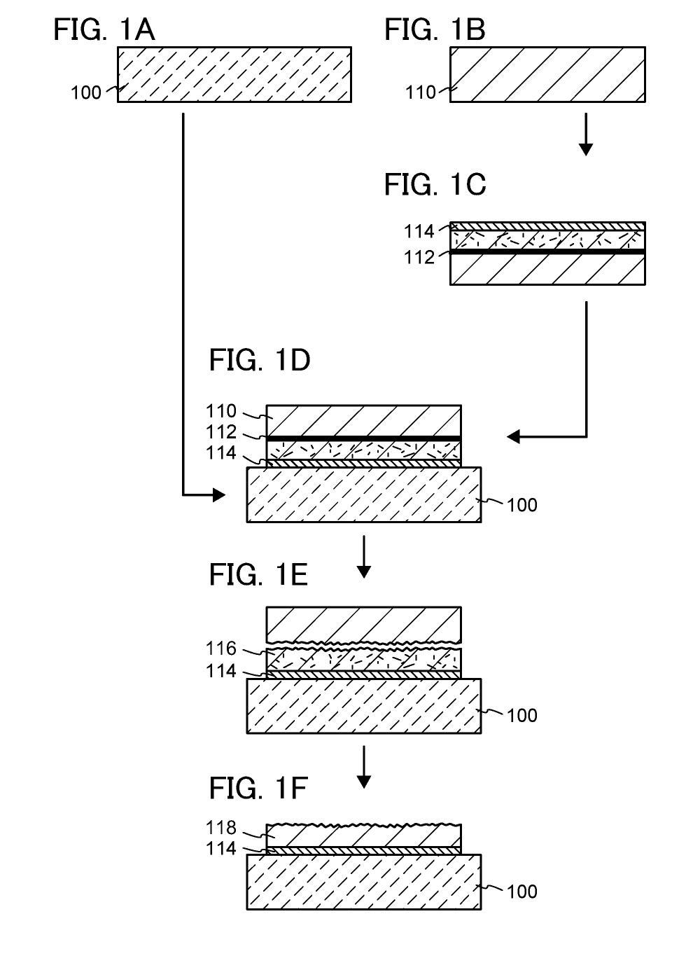

First, a base substrate 100 and a single crystal semiconductor substrate 110 are prepared (see FIGS. 1A and 1B).

As the base substrate 100, a substrate made from an insulator can be used. Specific examples thereof include: a variety of glass substrates used in the electronic industries, such as substrates formed with aluminosilicate glass, aluminoborosilicate glass, and barium borosilicate glass; a quartz substrate; a ceramic substrate; and a sapphire substrate. Note that when the above-mentioned glass substrate contains a large amount of boric acid (B₂O₃), the heat resistance of glass is improved; when it contains a larger amount of barium oxide (BaO) than boric acid, more-practical heat-resistant glass can be obtained. Therefore, it is preferable that a glass substrate containing more BaO than B₂O₃ be used. Since the strain point of the glass substrate containing more BaO than B₂O₃ can be, for example, 720° C. or higher, the glass substrate allows heat treatment at high temperature to be easily applied. Alternatively, a single crystal semiconductor substrate (for example, a single crystal silicon substrate) may be used as the base substrate 100. In this embodiment, the case of using a glass substrate as the base substrate 100 is described. When a glass substrate which can have a larger size and is inexpensive is used as the base substrate 100, a cost reduction can be achieved.

A surface of the base substrate 100 is preferably cleaned in advance. Specifically, the base substrate 100 is subjected to ultrasonic cleaning with a hydrochloric acid/hydrogen peroxide mixture (HPM), a sulfuric acid/hydrogen peroxide mixture (SPM), an ammonium hydroxide/hydrogen peroxide mixture (APM), diluted hydrogen fluoride (DHF), ozone water (O₃ water), or the like. Through such cleaning treatment, the surface planarity of the base substrate 100 can be improved and abrasive particles left on the surface of the base substrate 100 can be removed.

As the single crystal semiconductor substrate 110, for example, a single crystal semiconductor substrate formed with an element belonging to Group 14 of the periodic table, such as a single crystal silicon substrate, a single crystal germanium substrate, or a single crystal silicon germanium substrate, can be used. Alternatively, a compound semiconductor substrate of gallium arsenide, indium phosphide, or the like can be used. Typical commercially available silicon substrates are circular silicon substrates which are 5 inches (125 mm) in diameter, 6 inches (150 mm) in diameter, 8 inches (200 mm) in diameter, 12 inches (300 mm) in diameter, and 16 inches (400 mm) in diameter. Note that the shape of the single crystal semiconductor substrate 110 is not limited to a circular shape and for example, a single crystal semiconductor substrate which is processed into a rectangular shape can also be used. Alternatively, the single crystal semiconductor substrate 110 can be manufactured by a CZ method or a floating zone (FZ) method.

In view of removal of contaminants, it is preferable that a surface of the single crystal semiconductor substrate 110 be cleaned with a sulfuric acid/hydrogen peroxide mixture (SPM), an ammonium hydroxide/hydrogen peroxide mixture (APM), a hydrochloric acid/hydrogen peroxide mixture (HPM), diluted hydrogen fluoride (DHF), ozone water (O₃ water), or the like. Alternatively, diluted hydrogen fluoride and ozone water may be discharged alternately to clean the surface of the single crystal semiconductor substrate 110.

Next, an embrittled region 112 where the crystal structure is damaged is formed in the single crystal semiconductor substrate 110 at a predetermined depth from the surface, and then, the base substrate 100 and the single crystal semiconductor substrate 110 are bonded to each other with an insulating layer 114 interposed therebetween (see FIGS. 1C and 1D).

The embrittled region 112 can be formed by irradiating the single crystal semiconductor substrate 110 with ions of hydrogen or the like having kinetic energy.

The insulating layer 114 can be formed with a single layer or a stacked layer of insulating layers such as a silicon oxide film, a silicon oxynitride film, a silicon nitride film, or a silicon nitride oxide film. These films can be formed by a thermal oxidation method, a radical oxidation method, a CVD method, a sputtering method, or the like.

In this specification, a silicon oxynitride refers to a substance that contains more oxygen than nitrogen. For example, a silicon oxynitride is a substance including oxygen, nitrogen, silicon, and hydrogen in ranges of 50 at. % to 70 at. %, 0.5 at. % to 15 at. %, 25 at. % to 35 at. %, and 0.1 at. % to 10 at. %, respectively. A silicon nitride oxide refers to a substance that contains more nitrogen than oxygen. For example, a silicon nitride oxide is a substance including oxygen, nitrogen, silicon, and hydrogen in ranges of 5 at. % to 30 at. %, 20 at. % to 55 at. %, 25 at. % to 35 at. %, and 10 at. % to 30 at. %, respectively. Note that the above-mentioned ranges are obtained by measurement using Rutherford backscattering spectrometry (RBS) or hydrogen forward scattering (HFS). Moreover, the total of the percentages of the constituent elements does not exceed 100 at. %.

Note that before the single crystal semiconductor substrate 110 and the base substrate 100 are bonded to each other, the base substrate 100 and the insulating layer 114 formed over the single crystal semiconductor substrate 110 are preferably subjected to surface treatment.

As the surface treatment, plasma treatment, ozone treatment, megasonic cleaning, two fluid cleaning (a method for spraying functional water such as pure water or hydrogen-containing water with a carrier gas such as nitrogen), or a combination thereof can be performed. In particular, after plasma treatment is performed on the surface of at least one of the insulating layer 114 and the base substrate 100, ozone treatment, megasonic cleaning, two fluid cleaning, or the like is performed, whereby dust such as organic substances on the surface of the insulating layer 114 or the base substrate 100 can be removed and the surface can be made hydrophilic. As a result, bonding strength between the insulating layer 114 and the base substrate 100 can be increased.

Here, an example of ozone treatment is described. For example, ozone treatment can be performed on a surface of an object by irradiation with ultraviolet (UV) light in an atmosphere containing oxygen. Ozone treatment in which ultraviolet light irradiation is performed in an atmosphere containing oxygen is also called UV ozone treatment, ultraviolet ozone treatment, or the like. In an atmosphere containing oxygen, irradiation with ultraviolet light having a wavelength of less than 200 nm and ultraviolet light having a wavelength of 200 nm or more is performed, whereby ozone can be generated and singlet oxygen can be generated from ozone. Irradiation with ultraviolet light having a wavelength of less than 180 nm is performed, whereby ozone can be generated and singlet oxygen can be generated from ozone.

Examples of reactions which occur by irradiation with light having a wavelength of less than 200 nm and light having a wavelength of 200 nm or more in an atmosphere containing oxygen are described.

O₂+hv(λ₁ nm)→O(³P)+O(³P) (1)

O(³P)+O₂→O₃ (2)

O₃+hv(λ₂ nm)→O(¹D)+O₂ (3)

In the above reaction formula (1), irradiation with light (hv) having a wavelength (λ₁ nm) of less than 200 nm in an atmosphere containing oxygen (O₂) is performed to generate an oxygen atom (O(³P)) in a ground state. Next, in the reaction formula (2), an oxygen atom (O(³P)) in a ground state and oxygen (O₂) are reacted with each other to generate ozone (O₃). Then, in the reaction formula (3), irradiation with light having a wavelength (λ₂ nm) of 200 nm or more in an atmosphere containing generated ozone (O₃) is performed to generate singlet oxygen O(¹D) in an excited state. In an atmosphere containing oxygen, irradiation with ultraviolet light having a wavelength of less than 200 nm is performed to generate ozone, and irradiation with ultraviolet light having a wavelength of 200 nm or more is performed to decompose ozone and generate singlet oxygen. The ozone treatment as described above, for example, can be performed by irradiation with light from a low-pressure mercury lamp (λ₁=185 nm, λ₂=254 nm) in an atmosphere containing oxygen.

In addition, examples of reactions which occur by irradiation with light having a wavelength of less than 180 nm in an atmosphere containing oxygen are described.

O₂+hv(λ₃ nm)→O(¹D)+O(³P) (4)

O(³P)+O₂→O₃ (5)

O₃+hv(λ₃ nm)→O(¹D)+O₂ (6)

In the above reaction formula (4), irradiation with light having a wavelength (λ₃ nm) of less than 180 nm in an atmosphere containing oxygen (O₂) is performed to generate singlet oxygen O(¹D) in an excited state and an oxygen atom (O(³P)) in a ground state. Next, in the reaction formula (5), an oxygen atom (O(³P)) in a ground state and oxygen (O₂) are reacted with each other to generate ozone (O₃). In the reaction formula (6), irradiation with light having a wavelength (λ₃ nm) of less than 180 nm in an atmosphere containing generated ozone (O₃) is performed to generate singlet oxygen in an excited state and oxygen. In an atmosphere containing oxygen, irradiation with ultraviolet light having a wavelength of less than 180 nm is performed to generate ozone as well as to decompose ozone or oxygen and to generate singlet oxygen. The ozone treatment as described above, for example, can be performed by irradiation with light from a Xe excimer UV lamp (λ₃=172 nm) in an atmosphere containing oxygen.

Chemical bonding of an organic substance or the like attached to a surface of an object is cut with light having a wavelength of less than 200 nm, whereby the organic substance attached to the surface of the object, or the organic substance or the like whose chemical bonding is cut, can be removed by oxidative decomposition with ozone or singlet oxygen generated from ozone. By performing ozone treatment as described above, the hydrophilicity and cleanliness of the surface of the object can be increased, and favorable bonding can be performed.

In an atmosphere containing oxygen, ozone is generated by irradiation with ultraviolet light. Ozone is effective in removal of an organic substance attached to the surface of the object. In addition, singlet oxygen is also effective in removal of the organic substance attached to the surface of the object as much as or more than ozone. Ozone and singlet oxygen are examples of oxygen in an active state and collectively called active oxygen. As described with the above reaction formulae and the like, because there are reactions where ozone is generated in generating singlet oxygen or singlet oxygen is generated from ozone, such reactions where singlet oxygen contributes are also called ozone treatment for convenience.

Next, heat treatment is performed to cause separation at the embrittled region 112, whereby a single crystal semiconductor layer 116 is provided over the base substrate 100 with the insulating layer 114 interposed therebetween (see FIG. 1E).

By the heat treatment, the element added is separated out into microvoids which are formed in the embrittled region 112, and the internal stress is increased. By the increased pressure, a crack is generated in the embrittled region 112, and accordingly, the single crystal semiconductor substrate 110 is separated along the embrittled region 112. Because the insulating layer 114 is bonded to the base substrate 100, the single crystal semiconductor layer 116 which is separated from the single crystal semiconductor substrate 110 remains over the base substrate 100.

At this stage, a large number of defects resulting from the ion irradiation step, the separation step of the single crystal semiconductor layer 116, or the like exist in the single crystal semiconductor layer 116 (including its surface; the same applies hereinafter). Therefore, even if the single crystal semiconductor layer 116 in this state is subjected to laser light irradiation treatment, it is difficult to sufficiently reduce defects in the single crystal semiconductor layer 116 and to improve characteristics thereof. Thus, in an embodiment of the disclosed invention, heat treatment is performed before laser light irradiation treatment, thereby sufficiently reducing defects in the single crystal semiconductor layer 116 to form a single crystal semiconductor layer 118 (see FIG. 1F).

Specifically, heat treatment is performed at a temperature of 680° C. or higher, preferably, 700° C. or higher. When a glass substrate is used as the base substrate 100, the upper temperature limit can be determined from its allowable temperature limit, which is preferably based on its strain point. In other words, in the case of using a glass substrate, the heat treatment may be performed at a temperature higher than or equal to 680° C. and lower than the strain point. The length of heat treatment may be set as appropriate and is set to 1 hour or more, preferably, 3 hours or more in order to sufficiently reduce defects.

The aforementioned heat treatment can be performed using a diffusion furnace, a heating furnace such as a resistance heating furnace, a rapid thermal annealing (RTA) apparatus, or the like.

Note that in this embodiment, an example is described in which heat treatment for separating the single crystal semiconductor layer 116 and heat treatment for reducing defects in the single crystal semiconductor layer 116 are performed in separate steps; however, an embodiment of the disclosed invention should not be interpreted as being limited thereto. Heat treatment for separating the single crystal semiconductor layer 116 and heat treatment for reducing defects in the single crystal semiconductor layer 116 may be performed in the same step. In that case, the heat treatment for separating the single crystal semiconductor layer 116 and the heat treatment for reducing defects in the single crystal semiconductor layer 116 may be performed at the same temperature or different temperatures. When performed in the same step, the heat treatments are significantly effective in improving productivity and preventing contamination of the single crystal semiconductor layer 116, for example.

In addition, in this embodiment, the heat treatment for reducing defects in the single crystal semiconductor layer 116 is performed shortly after the heat treatment for separating the single crystal semiconductor layer 116; however, an embodiment of the disclosed invention should not be interpreted as being limited thereto. After the heat treatment for separating the single crystal semiconductor layer 116, etching treatment may be performed to remove a region including many defects at the surface of the single crystal semiconductor layer 116 or to improve the surface planarity of the single crystal semiconductor layer 116. The removal of the region including many defects at the surface of the single crystal semiconductor layer 116 is effective in shortening the length of heat treatment, for example. The improvement of the surface planarity of the single crystal semiconductor layer 116 is effective in reducing variation in semiconductor element characteristics or increasing the withstand voltage of a gate insulating film, for example. Note that the etching treatment may be either wet etching or dry etching.

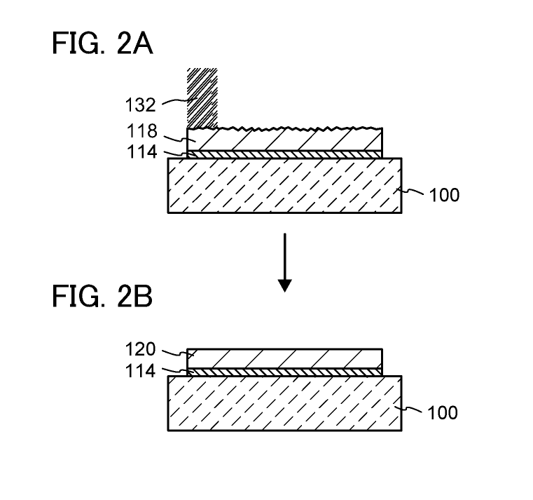

Next, a surface of the single crystal semiconductor layer 118 is irradiated with laser light 132, thereby further reducing defects to form a single crystal semiconductor layer 120 (see FIGS. 2A and 2B). Although there is no particular limitation on the atmosphere for laser light irradiation, if laser light irradiation is performed in an inert atmosphere or a reduced-pressure atmosphere, the surface planarity of the single crystal semiconductor layer 120 can be improved as compared to the case of an air atmosphere.

In an embodiment of the disclosed invention, although defects are sufficiently reduced in the single crystal semiconductor layer 118 through the heat treatment, defects may still remain in the single crystal semiconductor layer 118. The laser light irradiation treatment is performed to repair such defects. As illustrated in FIG. 2A, a surface of the single crystal semiconductor layer 118 is irradiated with the laser light 132 to melt at least a superficial portion of the single crystal semiconductor layer 118, whereby defects can be further reduced and the single crystal semiconductor layer 120 can be formed. The melting of the superficial portion of the single crystal semiconductor layer 118 enables defect reduction and surface planarization.

Note that it is preferable that the melting of the single crystal semiconductor layer 118 by irradiation with the laser light 132 be partial melting. This is because, if the single crystal semiconductor layer 118 is completely melted, it is microcrystallized due to disordered nucleation after being in a liquid phase, so that the crystallinity thereof decreases. On the other hand, by partial melting, crystal growth can be performed based on a non-melted solid phase portion. Therefore, crystal quality can be improved as compared to the case where the single crystal semiconductor layer 118 is completely melted. In addition, incorporation of oxygen, nitrogen, or the like from the insulating layer 114 can be suppressed. Note that “complete melting” means that the single crystal semiconductor layer 118 is melted to the interface with the insulating layer 114 and becomes a liquid state.

For the laser light irradiation, a pulsed laser is preferably used. This is because instantaneous and high-energy pulsed laser light can easily produce a partially melted state. The repetition rate is preferably, but not limited to, about 1 Hz to 10 MHz. Examples of the pulsed laser include an Ar laser, a Kr, laser, an excimer laser (ArF, KrF, XeCl) laser, a CO₂ laser, a YAG laser, a YVO₄ laser, a YLF laser, a YAlO₃ laser, a GdVO₄ laser, a Y₂O₃ laser, a ruby laser, an alexandrite laser, a Ti:sapphire laser, a copper vapor laser, a gold vapor laser, and the like. Note that a continuous-wave laser may be used if it can cause partial melting. Example of the continuous-wave laser include an Ar laser, a Kr laser, a CO₂ laser, a YAG laser, a YVO₄ laser, a YLF laser, a YAlO₃ laser, a GdVO₄ laser, a Y₂O₃ laser, a ruby laser, an alexandrite laser, a Ti:sapphire laser, a helium-cadmium laser, and the like.

The wavelength of the laser light 132 needs to be selected so that the laser light 132 is absorbed by the single crystal semiconductor layer 118. The wavelength may be determined in consideration of the skin depth of the single crystal semiconductor layer 118 with respect to the laser light and the like. For example, the wavelength can be set in the range of 250 nm to 700 nm. The energy density of the laser light 132 can be determined in consideration of the wavelength of the laser light 132, the skin depth of the single crystal semiconductor layer 118 with respect to the laser light, the thickness of the single crystal semiconductor layer 118, or the like. The energy density of the laser light 132 may be set in the range of 300 mJ/cm² to 1000 mJ/cm², for example. Note that the above range of the energy density is an example when a XeCl excimer laser (wavelength: 308 nm) is used as the pulsed laser.

The irradiation with the laser light 132 can be performed in an atmosphere containing oxygen such as an air atmosphere or in an inert atmosphere such as a nitrogen atmosphere or an argon atmosphere. In order to perform irradiation with the laser light 132 in an inert atmosphere, the irradiation with the laser light 132 may be performed in an airtight chamber while the atmosphere in the chamber is being controlled. In the case where a chamber is not used, an inert atmosphere can be obtained by blowing an inert gas such as a nitrogen gas to the surface which is irradiated with the laser light 132.

Note that in an inert atmosphere such as nitrogen, the planarity of the single crystal semiconductor layer 120 can be improved more effectively than in an air atmosphere. In addition, in an inert atmosphere, generation of cracks and ridges can be suppressed more effectively than in an air atmosphere, and the applicable energy density range for the laser light 132 is wider. Note that irradiation with the laser light 132 may be performed in a reduced-pressure atmosphere. When irradiation with the laser light 132 is performed in a reduced-pressure atmosphere, the same effects as those obtained by the irradiation in an inert atmosphere can be obtained.

Although not described in this embodiment, after the irradiation with the laser light 132 is performed as described above, a step of thinning the single crystal semiconductor layer 120 may be performed. In order to thin the single crystal semiconductor layer 120, one of dry etching and wet etching or a combination of both of the etchings may be employed.

Through the above steps, an SOI substrate having excellent characteristics can be obtained.

In an embodiment of the disclosed invention, heat treatment is performed before laser light irradiation treatment, and thus, defects in a single crystal semiconductor layer are reduced. Accordingly, even in the case of partial melting, an SOI substrate having sufficient characteristics can be obtained. A sufficient reduction of defects in advance can suppress crystal defect concentration in the vicinity of a boundary between a melted region and a non-melted region.

In addition, because defects are sufficiently reduced before laser light irradiation treatment, even if energy density of laser light varies to some extent, adverse effects on characteristics of a semiconductor layer can be reduced.

Note that the structure described in this embodiment can be used in appropriate combination with structures described in other embodiments or example of this specification.

### Embodiment 2

In this embodiment, anther example of a method for manufacturing a semiconductor substrate (an SOI substrate) will be described with reference to drawings.

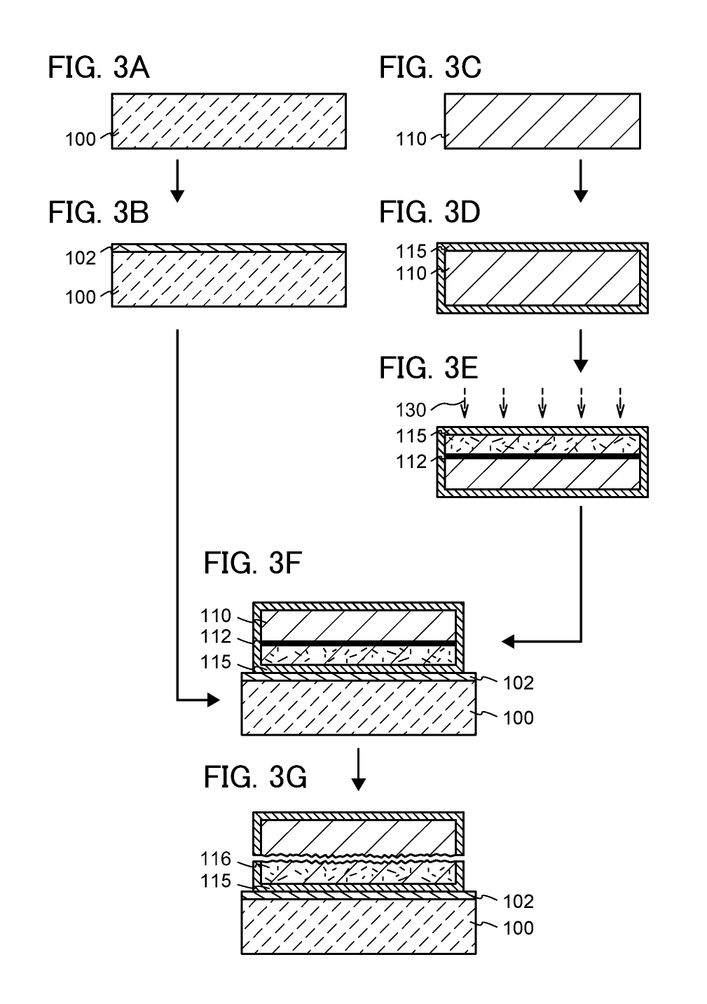

First, a base substrate 100 is prepared (see FIG. 3A). The details of the base substrate 100, for which Embodiment 1 can be referred to, are omitted here.

Next, a nitrogen-containing layer 102 (an insulating film containing nitrogen, such as a silicon nitride (SiNₓ) film or a silicon nitride oxide (SiNₓO_{y} (x>y)) film) is formed over a surface of the base substrate 100 (see FIG. 3B).

The nitrogen-containing layer 102 formed in this embodiment functions as a layer for bonding a single crystal semiconductor layer (as a bonding layer) in a later step. The nitrogen-containing layer 102 also functions as a barrier layer for preventing an impurity contained in the base substrate, such as sodium (Na), from diffusing into a single crystal semiconductor layer.

As mentioned above, the nitrogen-containing layer 102 is used as a bonding layer in this embodiment; thus, the nitrogen-containing layer 102 is preferably formed such that its surface has a predetermined degree of planarity. Specifically, the nitrogen-containing layer 102 is formed such that it has an average surface roughness (Rₐ) of 0.5 nm or less and a root-mean-square surface roughness (Rₘₛ) of 0.60 nm or less, preferably, an average surface roughness of 0.35 nm or less and a root-mean-square surface roughness of 0.45 nm or less. The thickness is preferably in the range of 10 nm to 200 nm, more preferably, 50 nm to 100 nm. With such a high degree of surface planarity, defective bonding of a single crystal semiconductor layer can be prevented.

Next, a single crystal semiconductor substrate 110 is prepared (see FIG. 3C). Note that the following steps for the single crystal semiconductor substrate 110 are performed after the steps for the base substrate 100; this is simply for convenience of explanation and the disclosed invention should not be interpreted as being limited to this order. The details of the single crystal semiconductor substrate 110, for which Embodiment 1 can be referred to, are omitted here.

In view of removal of contaminants, it is preferable that a surface of the single crystal semiconductor substrate 110 be cleaned with a sulfuric acid/hydrogen peroxide mixture (SPM), an ammonium hydroxide/hydrogen peroxide mixture (APM), a hydrochloric acid/hydrogen peroxide mixture (HPM), diluted hydrogen fluoride (DHF), ozone water (O₃ water), or the like. Alternatively, diluted hydrogen fluoride and ozone water may be discharged alternately to clean the surface of the single crystal semiconductor substrate 110.

Next, an oxide film 115 is formed on a surface of the single crystal semiconductor substrate 110 (see FIG. 3D).

The oxide film 115 can be formed with a single layer or a stacked layer of, for example, a silicon oxide film, a silicon oxynitride film, or the like. As a method for forming the oxide film 115, a thermal oxidation method, a CVD method, a sputtering method, or the like can be used. When the oxide film 115 is formed by a CVD method, a silicon oxide film may be formed using organosilane such as tetraethoxysilane (abbreviation: TEOS) (chemical formula: Si(OC₂H₅)₄).

In this embodiment, the oxide film 115 (here, a SiOₓ film (x>0)) is formed by thermal oxidation treatment of the single crystal semiconductor substrate 110. The thermal oxidation treatment is preferably performed in an oxidizing atmosphere to which halogen is added.

For example, thermal oxidation treatment of the single crystal semiconductor substrate 110 is performed in an oxidizing atmosphere to which chlorine (Cl) is added, whereby the oxide film 115 can be formed through chlorine oxidation. In this case, the oxide film 115 contains chlorine atoms.

Chlorine atoms contained in the oxide film 115 cause distortion in the oxide film 115. As a result, the moisture absorptance of the oxide film 115 is increased, and the diffusion rate is increased. In other words, when moisture exists at the surface of the oxide film 115, the moisture existing at the surface can be quickly absorbed into the oxide film 115 and diffused therein.

Further, with the chlorine atoms contained in the oxide film 115, heavy metal (such as Fe, Cr, Ni, or Mo) that is an extrinsic impurity can be captured, so that contamination of the single crystal semiconductor substrate 110 can be prevented. Moreover, after the bonding to the base substrate, impurities from the base substrate, such as Na, can be fixed, so that contamination of the single crystal semiconductor substrate 110 can be prevented.

Note that the halogen atoms contained in the oxide film 115 are not limited to chlorine atoms. Fluorine atoms may be contained in the oxide film 115. As a method for fluorine oxidation of the surface of the single crystal semiconductor substrate 110, a method in which the single crystal semiconductor substrate 110 is soaked in an HF solution and then subjected to thermal oxidation treatment in an oxidizing atmosphere, a method in which thermal oxidation treatment is performed in an oxidizing atmosphere to which NF₃ is added, or the like can be used.

Next, the single crystal semiconductor substrate 110 is irradiated with ions 130 accelerated by an electrical field, thereby forming an embrittled region 112 where the crystal structure is damaged, in the single crystal semiconductor substrate 110 at a predetermined depth (see FIG. 3E). The depth at which the embrittled region 112 is formed can be controlled by the kinetic energy, mass, charge, or incidence angle of the ions 130, or the like. The embrittled region 112 is formed at approximately the same depth as the average penetration depth of the ions 130. Therefore, the thickness of a single crystal semiconductor layer to be separated from the single crystal semiconductor substrate 110 can be controlled by the depth at which the ions 130 are added. For example, the average penetration depth may be controlled such that the thickness of a single crystal semiconductor layer is approximately 10 nm to 500 nm, preferably, 50 nm to 200 nm.

The above-described ion irradiation treatment can be performed with an ion-doping apparatus or an ion-implantation apparatus. As a typical example of the ion-doping apparatus, there is a non-mass-separation type apparatus in which plasma excitation of a process gas is performed and an object to be processed is irradiated with all kinds of ion species generated. In this apparatus, the object to be processed is irradiated with ion species of plasma without mass separation. In contrast, the ion-implantation apparatus is a mass-separation type apparatus. In the ion-implantation apparatus, mass separation of ion species of plasma is performed and the object to be processed is irradiated with ion species having predetermined masses.

In this embodiment, an example is described in which an ion-doping apparatus is used to add hydrogen to the single crystal semiconductor substrate 110. A gas containing hydrogen is used as a source gas. As for ions used for the irradiation, the proportion of H₃⁺ is preferably set high. Specifically, it is preferable that the proportion of H₃⁺ be set 50% or higher (more preferably, 80% or higher) with respect to the total amount of H⁺, H₂⁺, and H₃⁺. With a high proportion of H₃⁺, the efficiency of ion irradiation can be improved.

Note that heavy metal may also be added when the ion-doping apparatus is used; however, the ion irradiation is performed through the oxide film 115 containing halogen atoms, so that contamination of the single crystal semiconductor substrate 110 due to the heavy metal can be prevented as described above.

Next, a surface of the base substrate 100 and a surface of the single crystal semiconductor substrate 110 are disposed to face each other, and a surface of the nitrogen-containing layer 102 and a surface of the oxide film 115 are bonded to each other (see FIG. 3F).

In this embodiment, after the base substrate 100 and the single crystal semiconductor substrate 110 are disposed in close contact with each other with the nitrogen-containing layer 102 and the oxide film 115 interposed therebetween, a pressure of about 1 N/cm² to 500 N/cm², preferably, 11 N/cm² to 20 N/cm² is applied to one portion of the single crystal semiconductor substrate 110. Then, the nitrogen-containing layer 102 and the oxide film 115 start to be bonded to each other from the pressure-applied portion, and the bonding automatically spreads to the entire area. This bonding step is performed under the action of the Van der Waals force or hydrogen bonding and can be performed at room temperature.

Note that before the base substrate 100 and the single crystal semiconductor substrate 110 are bonded to each other, the oxide film 115 formed over the single crystal semiconductor substrate 110 and the nitrogen-containing layer 102 formed over the base substrate 100 are preferably subjected to surface treatment. As the surface treatment, plasma treatment, ozone treatment, megasonic cleaning, two fluid cleaning (a method for spraying functional water such as pure water or hydrogen-containing water with a carrier gas such as nitrogen), or a combination thereof can be performed. In particular, after plasma treatment is performed on the surface of at least one of the nitrogen-containing layer 102 and the oxide film 115, ozone treatment, megasonic cleaning, two fluid cleaning, or the like is performed, whereby dust such as organic substances on the surface of the nitrogen-containing layer 102 or the oxide film 115 can be removed and the surface can be made hydrophilic. As a result, bonding strength between the nitrogen-containing layer 102 and the oxide film 115 can be increased. For the details of the surface treatment, Embodiment 1 may be referred to.

After the nitrogen-containing layer 102 and the oxide film 115 are bonded to each other, hear treatment for increasing the bonding strength is preferably performed. This heat treatment is performed at a temperature at which separation at the embrittled region 112 does not occur (for example, from room temperature to less than 400° C.). Alternatively, the nitrogen-containing layer 102 and the oxide film 115 may be bonded to each other while being heated at a temperature within this range. The heat treatment can be performed using a diffusion furnace, a heating furnace such as a resistance heating furnace, a rapid thermal annealing (RTA) apparatus, a microwave heating apparatus, or the like.

Next, heat treatment is performed to separate the single crystal semiconductor substrate 110 at the embrittled region 112, whereby a single crystal semiconductor layer 116 is formed over the base substrate 100 with the nitrogen-containing layer 102 and the oxide film 115 interposed therebetween (see FIG. 3G).

By the heat treatment, the element added is separated out into microvoids which are formed in the embrittled region 112, and the internal stress is increased. By the increased pressure, a crack is generated in the embrittled region 112, and accordingly, the single crystal semiconductor substrate 110 is separated along the embrittled region 112. Because the oxide film 115 is bonded to the nitrogen-containing layer 102 over the base substrate 100, the single crystal semiconductor layer 116 which is separated from the single crystal semiconductor substrate 110 remains over the base substrate 100.

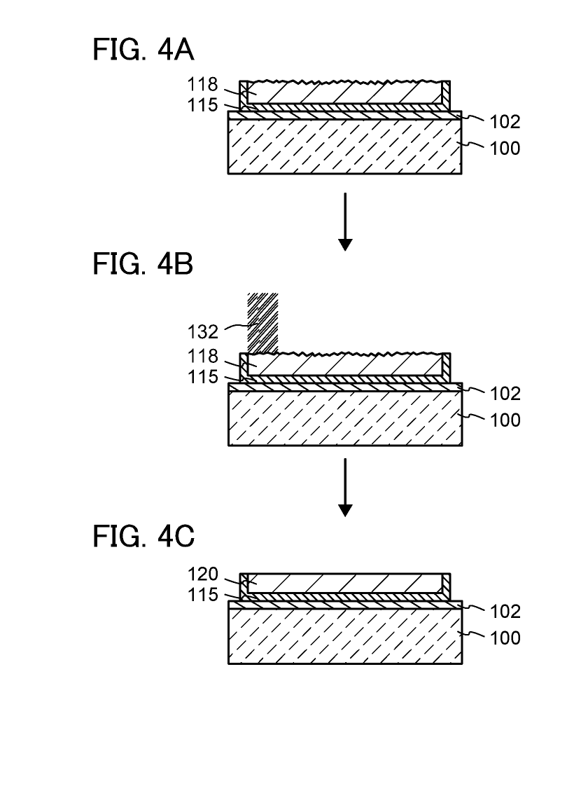

At this stage, a large number of defects resulting from the ion irradiation step, the separation step of the single crystal semiconductor layer 116, or the like exist in the single crystal semiconductor layer 116 (including its surface; the same applies hereinafter). Therefore, even if the single crystal semiconductor layer 116 in this state is subjected to laser light irradiation treatment, it is difficult to sufficiently reduce defects in the single crystal semiconductor layer 116 and to improve characteristics thereof. Thus, in an embodiment of the disclosed invention, heat treatment is performed before laser light irradiation treatment, thereby sufficiently reducing defects in the single crystal semiconductor layer 116 to form a single crystal semiconductor layer 118 (see FIG. 4A). The details of the heat treatment, for which Embodiment 1 can be referred to, are omitted here.

Next, a surface of the single crystal semiconductor layer 118 is irradiated with laser light 132, thereby further reducing defects to form a single crystal semiconductor layer 120 (see FIGS. 4B and 4C). Although there is no particular limitation on the atmosphere for laser light irradiation, if laser light irradiation is performed in an inert atmosphere or a reduced-pressure atmosphere, the surface planarity of the single crystal semiconductor layer 120 can be improved as compared to the case of an air atmosphere.

In an embodiment of the disclosed invention, although defects are sufficiently reduced in the single crystal semiconductor layer 118 through the heat treatment, defects may still remain in the single crystal semiconductor layer 118. The laser light irradiation treatment is performed to repair such defects. As illustrated in FIG. 4B, a surface of the single crystal semiconductor layer 118 is irradiated with the laser light 132 to melt at least a superficial portion of the single crystal semiconductor layer 118, whereby defects can be further reduced and the single crystal semiconductor layer 120 can be formed. The melting of the superficial portion of the single crystal semiconductor layer 118 enables defect reduction and surface planarization. Note that Embodiment 1 may be referred to for the other details of the laser light irradiation treatment.

Although not described in this embodiment, after the irradiation with the laser light 132 is performed as described above, a step of thinning the single crystal semiconductor layer 120 may be performed. In order to thin the single crystal semiconductor layer 120, one of dry etching and wet etching or a combination of both of the etchings may be employed.

Through the above steps, an SOI substrate having excellent characteristics can be obtained.

In an embodiment of the disclosed invention, heat treatment is performed before laser light irradiation treatment, and thus, defects in a single crystal semiconductor layer are reduced. Accordingly, even in the case of partial melting, an SOI substrate having sufficient characteristics can be obtained. A sufficient reduction of defects in advance can suppress crystal defect concentration in the vicinity of a boundary between a melted region and a non-melted region.

In addition, because defects are sufficiently reduced before laser light irradiation treatment, even if energy density of laser light varies to some extent, adverse effects on characteristics of a semiconductor layer can be reduced.

Note that the structure described in this embodiment can be used in appropriate combination with structures described in other embodiments or example of this specification.

### Embodiment 3

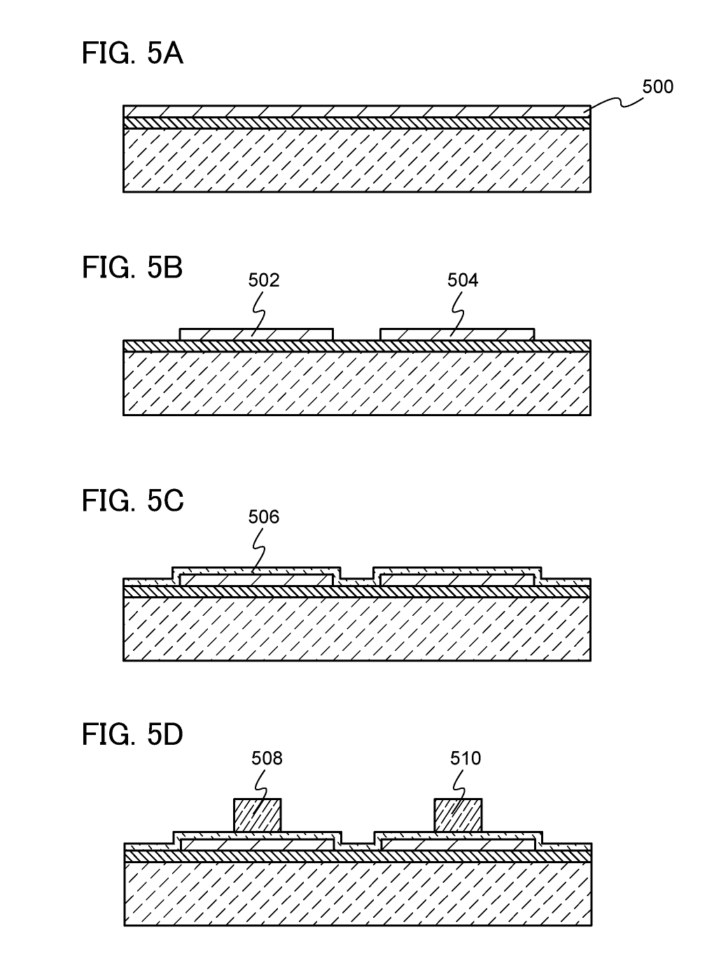

In this embodiment, a method for manufacturing a semiconductor device using the above-described semiconductor substrate will be described with reference to FIGS. 5A to 5D, FIGS. 6A to 6D, and FIGS. 7A and 7B. Here, a method for manufacturing a semiconductor device including a plurality of transistors as an example of the semiconductor device is described. Note that various semiconductor devices can be formed with the use of a combination of transistors described below.

FIG. 5A is a cross-sectional view of a semiconductor substrate which is manufactured in accordance with Embodiment 1.

In order to control threshold voltages of TFTs, a p-type impurity element such as boron, aluminum, or gallium or an n-type impurity element such as phosphorus or arsenic may be added to a semiconductor layer 500 (corresponding to the single crystal semiconductor layer 120 in Embodiment 1). A region to which the impurity element is added and the kind of impurity element to be added can be changed as appropriate. For example, a p-type impurity element is added to a formation region of an n-channel TFT, and an n-type impurity element is added to a formation region of a p-channel TFT. The above impurity element may be added at a dose of approximately 1×10¹⁵/cm² to 1×10¹⁷/cm². Then, the semiconductor layer 500 is divided into an island shape to form a semiconductor film 502 and a semiconductor film 504 (see FIG. 5B).

Next, a gate insulating film 506 is formed to cover the semiconductor film 502 and the semiconductor film 504 (see FIG. 5C). Here, a single-layer silicon oxide film is formed by a plasma CVD method. Alternatively, a film containing silicon oxynitride, silicon nitride oxide, silicon nitride, hafnium oxide, aluminum oxide, tantalum oxide, or the like may be formed to have a single-layer structure or a stacked structure as the gate insulating film 506.

As a manufacturing method other than a plasma CVD method, a sputtering method or a method using oxidation or nitridation by high density plasma treatment can be given. High-density plasma treatment is performed using, for example, a mixed gas of a noble gas such as helium, argon, krypton, or xenon and a gas such as oxygen, nitrogen oxide, ammonia, nitrogen, or hydrogen. In this case, if plasma excitation is performed by introduction of microwaves, plasma with low electron temperature and high density can be generated. The surfaces of the semiconductor films are oxidized or nitrided with oxygen radicals (OH radicals may be included) or nitrogen radicals (NH radicals may be included) which are generated by such high-density plasma, whereby the insulating film is formed to a thickness of 1 nm to 20 nm, preferably, 2 nm to 10 nm to be in contact with the semiconductor films.

Since the oxidation or nitridation of the semiconductor films by the above-described high-density plasma treatment is a solid-phase reaction, the interface state density between the gate insulating film 506 and each of the semiconductor films 502 and 504 can be drastically reduced. Further, when the semiconductor films are directly oxidized or nitrided by the high-density plasma treatment, variation in the thickness of the insulating film to be formed can be suppressed. Since the semiconductor films are single crystal films, even when the surfaces of the semiconductor films are oxidized by a solid-phase reaction by using the high-density plasma treatment, a gate insulating film with favorable uniformity and low interface state density can be formed. When an insulating film formed by high-density plasma treatment as described above is used for a part or whole of the gate insulating film of a transistor, variation in characteristics can be suppressed.

Alternatively, the gate insulating film 506 may be formed by thermally oxidizing the semiconductor film 502 and the semiconductor film 504. In the case of such thermal oxidation, it is necessary to use a glass substrate having a certain degree of heat resistance.

Note that after a gate insulating film 506 containing hydrogen is formed, hydrogen contained in the gate insulating film 506 may be dispersed into the semiconductor film 502 and the semiconductor film 504 by performing heat treatment at a temperature of 350° C. to 450° C. In this case, the gate insulating film 506 can be formed with silicon nitride or silicon nitride oxide by a plasma CVD method. If hydrogen is supplied to the semiconductor film 502 and the semiconductor film 504 in this manner, defects in the semiconductor film 502, in the semiconductor film 504, at the interface between the gate insulating film 506 and the semiconductor film 502, and at the interface between the gate insulating film 506 and the semiconductor film 504 can be effectively reduced.

Next, a conductive film is formed over the gate insulating film 506, and then, the conductive film is processed (patterned) into a predetermined shape, whereby an electrode 508 and an electrode 510 are formed over the semiconductor film 502 and the semiconductor film 504, respectively (see FIG. 5D). The conductive film can be formed by a CVD method, a sputtering method, or the like. The conductive film can be formed using a material such as tantalum (Ta), tungsten (W), titanium (Ti), molybdenum (Mo), aluminum (Al), copper (Cu), chromium (Cr), or niobium (Nb). Alternatively, an alloy material containing the above-mentioned metal as its main component or a compound containing the above-mentioned metal can also be used. Further alternatively, a semiconductor material, such as polycrystalline silicon which is obtained by doping a semiconductor with an impurity element that imparts a conductivity type, may be used.

Although the electrodes 508 and 510 are formed using a single-layer conductive film in this embodiment, a semiconductor device is not limited to this structure. Each of the electrodes 508 and 510 may be formed with plural stacked conductive films. In the case of a two-layer structure, for example, a molybdenum film, a titanium film, a titanium nitride film, or the like may be used as the lower layer, and an aluminum film or the like may be used as the upper layer. In the case of a three-layer structure, a stacked structure of a molybdenum film, an aluminum film, and a molybdenum film, a stacked structure of a titanium film, an aluminum film, and a titanium film, or the like may be used.

Note that a mask used for forming the electrodes 508 and 510 may be formed using a material such as silicon oxide or silicon nitride oxide. In this case, a step of forming a mask by patterning a silicon oxide film, a silicon nitride oxide film, or the like is additionally needed. However, the amount of decrease in film thickness of the mask in etching is smaller than that in the case of using a resist material; thus, the electrodes 508 and 510 with a more precise shape can be formed. Alternatively, the electrodes 508 and 510 may be selectively formed by a droplet discharge method without using a mask. Here, a droplet discharge method refers to a method in which droplets containing a predetermined composition are discharged or ejected to form a predetermined pattern, and includes an ink-jet method and the like in its category.

Alternatively, the electrodes 508 and 510 can be formed by etching the conductive film to have a desired tapered shape by an inductively coupled plasma (ICP) etching method with appropriate adjustment of etching conditions (e.g., the amount of electric power applied to a coiled electrode, the amount of electric power applied to a substrate-side electrode, the temperature of the substrate-side electrode, and the like). The tapered shape can also be adjusted with the shape of the mask. Note that as an etching gas, a chlorine based gas such as chlorine, boron chloride, silicon chloride, or carbon tetrachloride, a fluorine based gas such as carbon tetrafluoride, sulfur fluoride, or nitrogen fluoride, oxygen, or the like can be used as appropriate.

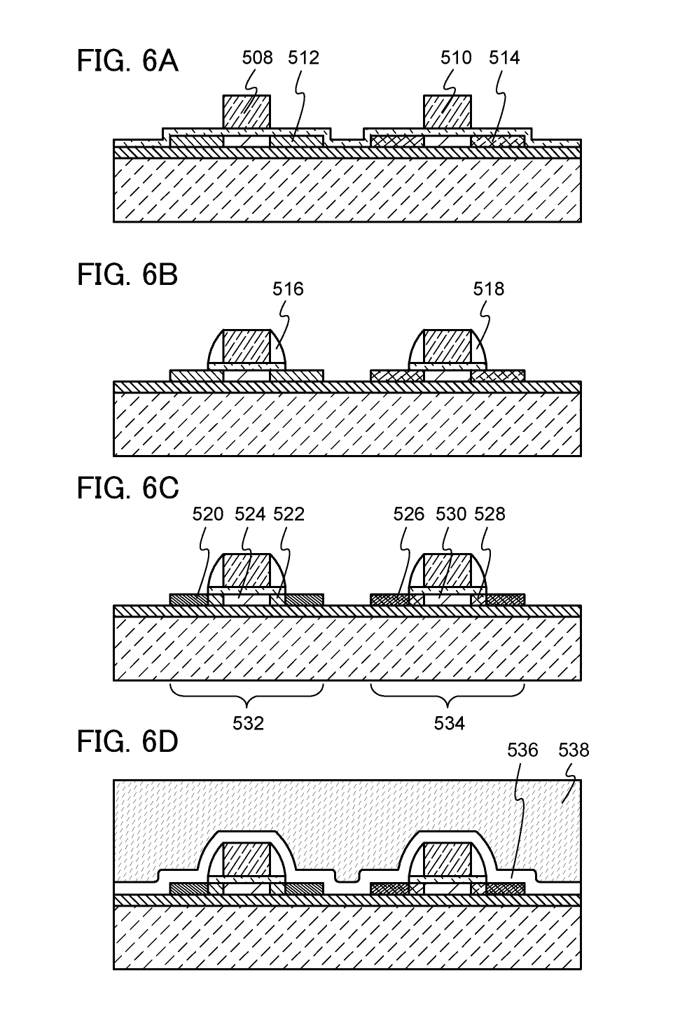

Next, an impurity element imparting one conductivity type is added to the semiconductor film 502 and the semiconductor film 504 using the electrodes 508 and 510 as masks (see FIG. 6A). In this embodiment, an impurity element imparting n-type conductivity (e.g., phosphorus or arsenic) is added to the semiconductor film 502, and an impurity element imparting p-type conductivity (e.g., boron) is added to the semiconductor film 504. Note that when the impurity element imparting n-type conductivity is added to the semiconductor film 502, the semiconductor film 504 to which the p-type impurity element is added is covered with a mask or the like so that the impurity element imparting n-type conductivity is added selectively. When the impurity element imparting p-type conductivity is added to the semiconductor film 504, the semiconductor film 502 to which the impurity element imparting n-type conductivity is added is covered with a mask or the like so that the impurity element imparting p-type conductivity is added selectively. Alternatively, after one of the impurity element imparting p-type conductivity and the impurity element imparting n-type conductivity is added to the semiconductor films 502 and 504, the other of the impurity element imparting n-type conductivity and the impurity element imparting p-type conductivity may be added to only one of the semiconductor films at a higher concentration. By the addition of the impurity elements, impurity regions 512 and impurity regions 514 are formed in the semiconductor film 502 and the semiconductor film 504, respectively.

Next, sidewalls 516 are formed on side surfaces of the electrode 508, and sidewalls 518 are formed on side surfaces of the electrode 510 (see FIG. 6B). The sidewalls 516 and 518 can be formed by, for example, newly forming an insulating film to cover the gate insulating film 506 and the electrodes 508 and 510 and by partially etching the newly formed insulating film by anisotropic etching mainly in a perpendicular direction. Note that the gate insulating film 506 may also be etched partially by the anisotropic etching described above. For the insulating film used for forming the sidewalls 516 and 518, a film containing silicon, silicon oxide, silicon nitride, silicon oxynitride, silicon nitride oxide, an organic material, or the like may be formed to have a single layer structure or a stacked structure by a plasma CVD method, a sputtering method, or the like. In this embodiment, a 100 nm thick silicon oxide film is formed by a plasma CVD method. In addition, as an etching gas, a mixed gas of CHF₃ and helium can be used. Note that the steps of forming the sidewalls 516 and 518 are not limited to the steps described here.

Next, impurity elements each imparting one conductivity type are added to the semiconductor films 502 and 504 using the gate insulating film 506, the electrodes 508 and 510, and the sidewalls 516 and 518 as masks (see FIG. 6C). Note that the impurity elements imparting the same conductivity types as the impurity elements which have been added to the semiconductor films 502 and 504 in the previous step are added to the semiconductor films 502 and 504 at higher concentrations. In this embodiment, when the impurity element imparting n-type conductivity is added to the semiconductor film 502, the semiconductor film 504 to which the p-type impurity element is added is covered with a mask or the like so that the impurity element imparting n-type conductivity is added selectively. When the impurity element imparting p-type conductivity is added to the semiconductor film 504, the semiconductor film 502 to which the impurity element imparting n-type conductivity is added is covered with a mask or the like so that the impurity element imparting p-type conductivity is added selectively.

By the addition of the impurity element, a pair of high-concentration impurity regions 520, a pair of low-concentration impurity regions 522, and a channel formation region 524 are formed in the semiconductor film 502. In addition, by the addition of the impurity element, a pair of high-concentration impurity regions 526, a pair of low-concentration impurity regions 528, and a channel formation region 530 are formed in the semiconductor film 504. The high-concentration impurity regions 520 and the high-concentration impurity regions 526 each function as a source or a drain, and the low-concentration impurity regions 522 and the low-concentration impurity regions 528 each function as a lightly doped drain (LDD) region.

Note that the sidewalls 516 formed over the semiconductor film 502 and the sidewalls 518 formed over the semiconductor film 504 may be formed so as to have the same length or different lengths in a direction in which carriers travel (in a direction parallel to a so-called channel length). Each of the sidewalls 518 over the semiconductor film 504 which constitutes part of a p-channel transistor is preferably formed larger than each of the sidewalls 516 over the semiconductor film 502 which constitutes part of an n-channel transistor. This is because boron which is added for forming a source and a drain in the p-channel transistor is easily diffused and a short channel effect is easily induced. By increasing the lengths of the sidewalls 518 of the p-channel transistor, boron can be added to the source and the drain at high concentration, whereby the resistance of the source and the drain can be reduced.

In order to further reduce the resistance of the source and the drain, a silicide layer may be formed by forming silicide in part of the semiconductor films 502 and 504. The silicide is formed by placing a metal in contact with the semiconductor films and causing a reaction between the metal and silicon in the semiconductor films by heat treatment (e.g., a GRTA method, an LRTA method, or the like). For the silicide layer, cobalt silicide or nickel silicide may be used. In the case where the semiconductor films 502 and 504 are thin, silicide reaction may proceed to the bottoms of the semiconductor films 502 and 504. As a metal material used for the siliciding, the following can be used: titanium (Ti), nickel (Ni), tungsten (W), molybdenum (Mo), cobalt (Co), zirconium (Zr), hafnium (Hf), tantalum (Ta), vanadium (V), neodymium (Nd), chromium (Cr), platinum (Pt), palladium (Pd), or the like. Further, a silicide layer can also be formed by laser light irradiation or the like.

Through the aforementioned steps, an n-channel transistor 532 and a p-channel transistor 534 are formed. Note that although conductive films each serving as a source electrode or a drain electrode have not been formed at the stage shown in FIG. 6C, a structure including these conductive films each serving as a source electrode or a drain electrode may also be referred to as a transistor.

Next, an insulating film 536 is formed to cover the n-channel transistor 532 and the p-channel transistor 534 (see FIG. 6D). The insulating film 536 is not always necessary; however, the formation of the insulating film 536 can prevent impurities such as an alkali metal and an alkaline earth metal from penetrating the n-channel transistor 532 and the p-channel transistor 534. Specifically, the insulating film 536 is preferably formed using a material such as silicon oxide, silicon nitride, silicon oxynitride, silicon nitride oxide, aluminum nitride, aluminum oxide, or the like. In this embodiment, a silicon nitride oxide film with a thickness of approximately 600 nm is used as the insulating film 536. In this case, the above-described hydrogenation step may be performed after the silicon nitride oxide film is formed. Note that although the insulating film 536 is formed to have a single-layer structure in this embodiment, it is needless to say that the insulating film 536 may have a stacked structure. For example, in the case of a two-layer structure, the insulating film 536 may have a stacked structure of a silicon oxynitride film and a silicon nitride oxide film.

Next, an insulating film 538 is formed over the insulating film 536 to cover the n-channel transistor 532 and the p-channel transistor 534. The insulating film 538 may be formed using an organic material having heat resistance, such as polyimide, acrylic, benzocyclobutene, polyamide, or epoxy. Other than such an organic material, it is also possible to use a low-dielectric constant material (a low-k material), a siloxane based resin, silicon oxide, silicon nitride, silicon oxynitride, silicon nitride oxide, phosphosilicate glass (PSG), borophosphosilicate glass (BPSG), alumina, or the like. Here, the siloxane based resin corresponds to a resin including a Si—O—Si bond which is formed using a siloxane based material as a starting material. The siloxane based resin may include, besides hydrogen, at least one of fluorine, an alkyl group, and aromatic hydrocarbon as a substituent. Alternatively, the insulating film 538 may be formed by stacking plural insulating films using any of these materials.

For the formation of the insulating film 538, the following method can be employed depending on the material of the insulating film 538: a CVD method, a sputtering method, an SOG method, a spin coating method, a dipping method, a spray coating method, a droplet discharge method (e.g., an ink-jet method, screen printing, offset printing, or the like), a doctor knife, a roll coater, a curtain coater, a knife coater, or the like.

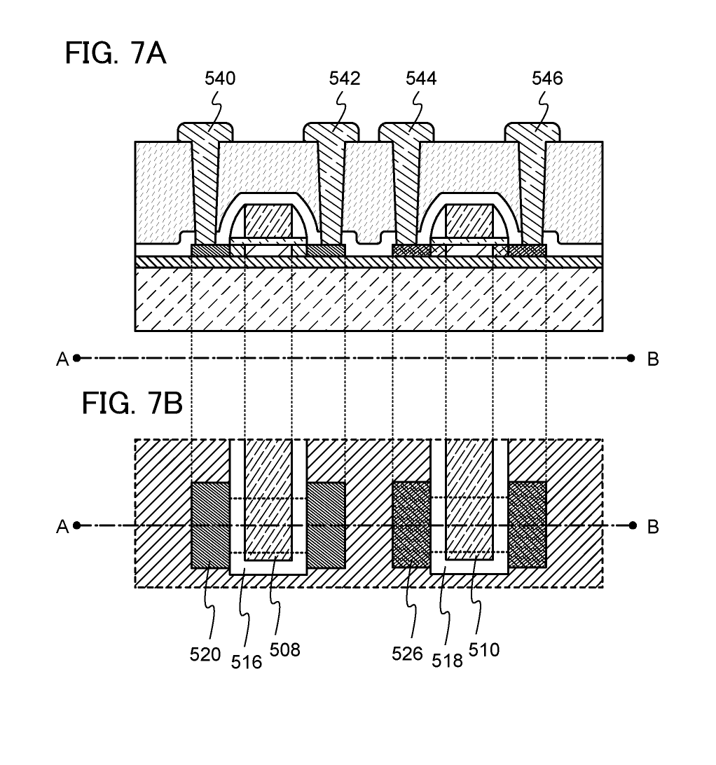

Next, contact holes are formed in the insulating films 536 and 538 so that each of the semiconductor films 502 and 504 is partially exposed. Then, conductive films 540 and 542 are formed in contact with the semiconductor film 502 through the contact holes, and conductive films 544 and 546 are formed in contact with the semiconductor film 504 through the contact holes (see FIG. 7A). The conductive films 540, 542, 544, and 546 serve as source electrodes and drain electrodes of the transistors. Note that in this embodiment, as an etching gas used for forming the contact holes, a mixed gas of CHF₃ and He is employed; however, the etching gas is not limited thereto.

The conductive films 540, 542, 544, and 546 can be formed by a CVD method, a sputtering method, or the like. Specifically, the conductive films 540, 542, 544, and 546 can be formed using aluminum (Al), tungsten (W), titanium (Ti), tantalum (Ta), molybdenum (Mo), nickel (Ni), platinum (Pt), copper (Cu), gold (Au), silver (Ag), manganese (Mn), neodymium (Nd), carbon (C), silicon (Si), or the like. Moreover, an alloy containing the above-mentioned material as its main component or a compound containing the above-mentioned material may be used. The conductive films 540, 542, 544, and 546 may each have a single-layer structure or a stacked structure.

As examples of an alloy containing aluminum as its main component, an alloy containing aluminum as its main component and also containing nickel, and an alloy containing aluminum as its main component and also containing nickel and one or both of carbon and silicon can be given. Since aluminum and aluminum silicon (Al—Si) have low resistance and are inexpensive, aluminum and aluminum silicon are suitable as a material for forming the conductive films 540, 542, 544, and 546. In particular, aluminum silicon is preferable because generation of a hillock due to resist baking at the time of patterning can be suppressed. Further, a material in which Cu is mixed into aluminum at approximately 0.5% may be used instead of silicon.

In the case where each of the conductive films 540, 542, 544, and 546 is formed to have a stacked structure, a stacked structure of a barrier film, an aluminum silicon film, and a barrier film, a stacked structure of a barrier film, an aluminum silicon film, a titanium nitride film, and a barrier film, or the like may be employed, for example. Note that a barrier film refers to a film formed using titanium, a nitride of titanium, molybdenum, a nitride of molybdenum, or the like. By forming the conductive films such that an aluminum silicon film is interposed between barrier films, generation of hillocks of aluminum or aluminum silicon can be further prevented. Moreover, by forming the barrier film using titanium that is a highly reducible element, even if a thin oxide film is formed on the semiconductor films 502 and 504, the oxide film is reduced by the titanium contained in the barrier film, whereby favorable contact can be obtained between the conductive films 540 and 542 and the semiconductor film 502 and between the conductive films 544 and 546 and the semiconductor film 504. Further, it is also possible to stack a plurality of barrier films. In that case, for example, each of the conductive films 540, 542, 544, and 546 can be formed to have a five-layer structure of titanium, titanium nitride, aluminum silicon, titanium, and titanium nitride in order from the bottom or a stacked structure of more than five layers.

For the conductive films 540, 542, 544, and 546, tungsten silicide formed by a chemical vapor deposition method using a WF₆ gas and a SiH₄ gas may be used. Alternatively, tungsten formed by hydrogen reduction of WF₆ may be used for the conductive films 540, 542, 544, and 546.

Note that the conductive films 540 and 542 are connected to the high-concentration impurity regions 520 of the n-channel transistor 532. The conductive films 544 and 546 are connected to the high-concentration impurity regions 526 of the p-channel transistor 534.

FIG. 7B is a plan view of the n-channel transistor 532 and the p-channel transistor 534 which are illustrated in FIG. 7A. Here, a cross-sectional view taken along the line A-B in FIG. 7B corresponds to FIG. 7A. Note that in FIG. 7B, the conductive films 540, 542, 544, and 546, the insulating films 536 and 538, and the like are omitted for simplicity.

Note that although the case where the n-channel transistor 532 and the p-channel transistor 534 each include one electrode serving as a gate electrode (the case where the n-channel transistor 532 and the p-channel transistor 534 include the electrodes 508 and 510) is described in this embodiment as an example, the disclosed invention is not limited to this structure. The transistors may have a multi-gate structure in which a plurality of electrodes serving as gate electrodes are included and electrically connected to one another.

In this embodiment, the transistors are formed using a single crystal semiconductor film. Accordingly, the transistors have a higher switching speed than those formed using an amorphous semiconductor film, a non-single-crystal semiconductor film, or the like. In addition, in this embodiment, a uniform and favorable single crystal semiconductor film is used; thus, variation in characteristics among transistors can be sufficiently suppressed. Accordingly, a semiconductor device having excellent characteristics can be provided.

This embodiment can be implemented in combination with any of other embodiments and examples as appropriate.

### Embodiment 4

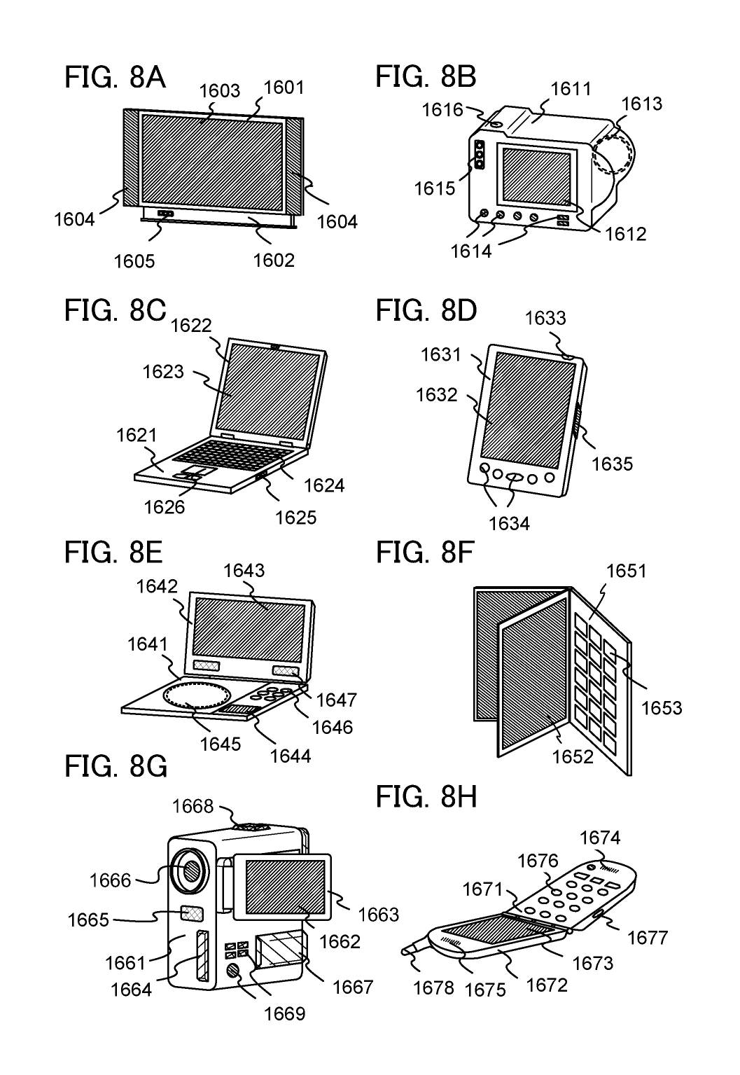

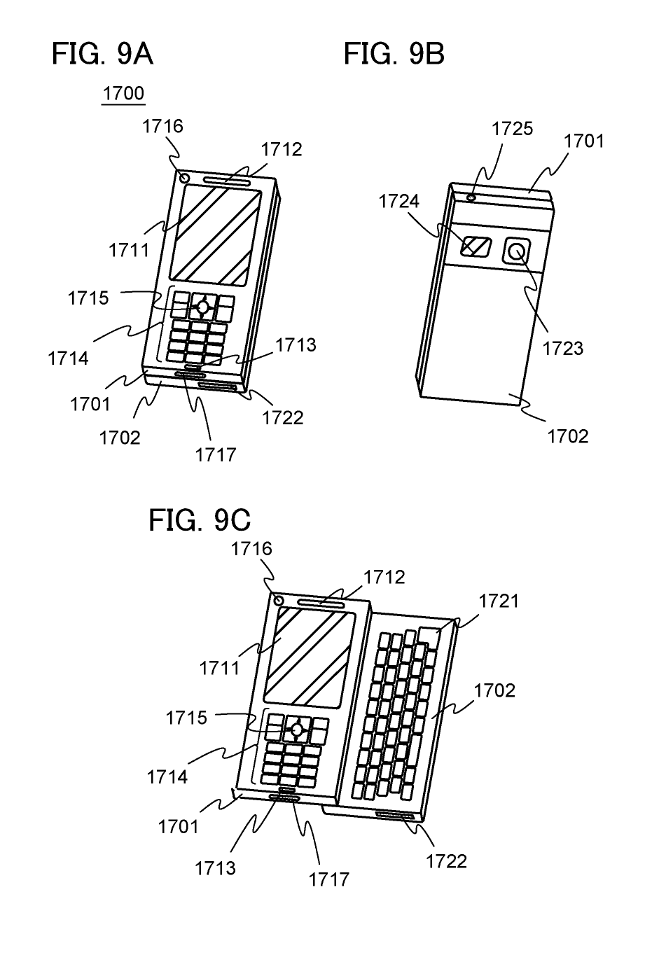

In this embodiment, electronic devices each including a semiconductor device manufactured in any of the above embodiments, particularly, a display device, are described with reference to FIGS. 8A to 8H and FIGS. 9A to 9C.

Examples of electronic devices manufactured using a semiconductor device (particularly, a display device) are as follows: cameras such as video cameras and digital cameras; goggle-type displays (head-mounted displays); navigation systems; sound reproduction systems (car audio systems and the like); computers; game machines; portable information terminals (mobile computers, cellular phones, portable game machines, electronic book readers, and the like); image reproduction devices provided with recording media (specifically, devices that are each capable of reproducing data stored in a recording medium such as a digital versatile disc (DVD) and that each have a display capable of displaying images therein); and the like.

FIG. 8A is a diagram of a television receiver or a monitor of a personal computer, which includes a housing 1601, a support 1602, a display portion 1603, a speaker portion 1604, a video input terminal 1605, and the like. A semiconductor device according to an embodiment of the disclosed invention is used in the display portion 1603. According to an embodiment of the disclosed invention, a television receiver or a monitor of a personal computer with high reliability and high performance can be provided at a low price.

FIG. 8B is a diagram of a digital camera. On the front side of a main body 1611, an image receiving portion 1613 is provided, and on the top side of the main body 1611, a shutter button 1616 is provided. Furthermore, on the back side of the main body 1611, a display portion 1612, operation keys 1614, and an external connection port 1615 are provided. A semiconductor device according to an embodiment of the disclosed invention is used in the display portion 1612. According to an embodiment of the disclosed invention, a digital camera with high reliability and high performance can be provided at a low price.

FIG. 8C is a diagram of a notebook personal computer. In a main body 1621, a keyboard 1624, an external connection port 1625, and a pointing device 1626 are provided. Furthermore, a housing 1622 that has a display portion 1623 is attached to the main body 1621. A semiconductor device according to an embodiment of the disclosed invention is used in the display portion 1623. According to an embodiment of the disclosed invention, a notebook personal computer with high reliability and high performance can be provided at a low price.

FIG. 8D is a diagram of a mobile computer, which includes a main body 1631, a display portion 1632, a switch 1633, operation keys 1634, an infrared port 1635, and the like. An active matrix display device is provided in the display portion 1632. A semiconductor device according to an embodiment of the disclosed invention is used in the display portion 1632. According to an embodiment of the disclosed invention, a mobile computer with high reliability and high performance can be provided at a low price.

FIG. 8E is a diagram of an image reproduction device. In a main body 1641, a display portion 1644, a storage media reading portion 1645, and operation keys 1646 are provided. Furthermore, a housing 1642 that has a speaker portion 1647 and a display portion 1643 is attached to the main body 1641. A semiconductor device according to an embodiment of the disclosed invention is used in each of the display portions 1643 and 1644. According to an embodiment of the disclosed invention, an image reproduction device with high reliability and high performance can be provided at a low price.

FIG. 8F is a diagram of an electronic book reader. In a main body 1651, operation keys 1653 are provided. Furthermore, a plurality of display portions 1652 is attached to the main body 1651. A semiconductor device according to an embodiment of the disclosed invention is used in each of the display portions 1652. According to an embodiment of the disclosed invention, an electronic book reader with high reliability and high performance can be provided at a low price.

FIG. 8G is a diagram of a video camera. In a main body 1661, an external connection port 1664, a remote control receiving portion 1665, an image receiving portion 1666, a battery 1667, an audio input portion 1668, and operation keys 1669 are provided. Furthermore, a housing 1663 that has a display portion 1662 is attached to the main body 1661. A semiconductor device according to an embodiment of the disclosed invention is used in the display portion 1662. According to an embodiment of the disclosed invention, a video camera with high reliability and high performance can be provided at a low price.

FIG. 8H is a diagram of a cellular phone, which includes a main body 1671, a housing 1672, a display portion 1673, an audio input portion 1674, an audio output portion 1675, operation keys 1676, an external connection port 1677, an antenna 1678, and the like. A semiconductor device according to an embodiment of the disclosed invention is used in the display portion 1673. According to an embodiment of the disclosed invention, a cellular phone with high reliability and high performance can be provided at a low price.

FIGS. 9A to 9C illustrate an example of a structure of a portable electronic device 1700 having both a function as a telephone and a function as an information terminal. FIG. 9A is a front view, FIG. 9B is a rear view, and FIG. 9C is a development view. The portable electronic device 1700 is an electronic device, a so-called smartphone, which functions as both a telephone and an information terminal and is capable of conducting a variety of data processing besides voice calls.

The portable electronic device 1700 includes a housing 1701 and a housing 1702. The housing 1701 is provided with a display portion 1711, a speaker 1712, a microphone 1713, operation keys 1714, a pointing device 1715, a camera lens 1716, an external connection terminal 1717, and the like. The housing 1702 is provided with a keyboard 1721, an external memory slot 1722, a camera lens 1723, a light 1724, an earphone terminal 1725, and the like. Moreover, an antenna is built in the housing 1701. In addition to the structure described above, a non-contact IC chip, a small size memory device, or the like can be built therein.

A semiconductor device according to an embodiment of the disclosed invention is incorporated in the display portion 1711. Note that an image displayed in the display portion 1711 (and a direction in which the image is displayed) changes variously with respect to the usage pattern of the portable electronic device 1700. Moreover, the display portion 1711 and the camera lens 1716 are provided on the same surface, voice calls with images (so-called video calls) are possible. Note that the speaker 1712 and the microphone 1713 can be used not only for voice calls but also for recording, reproducing, or the like. In the case where a still image and a moving image are shot by using the camera lens 1723 (and the light 1724), the display portion 1711 is used as a finder. The operation keys 1714 are used for incoming/outgoing of phone calls, inputting simple information such as e-mail, screen scrolling, moving cursor, and the like.

The housings 1701 and 1702 overlapping with each other (FIG. 9A) slide and can be developed as illustrated in FIG. 9C, so that the portable electronic device 1700 can be used as an information terminal. In this case, smooth operation with the keyboard 1721 and the pointing device 1715 can be performed. The external connection terminal 1717 can be connected to various cables such as an AC adopter or a USB cable; thus, the portable electronic device 1700 can be charged or can perform data communication with a computer or the like. Moreover, by inserting a recording medium into the external memory slot 1722, the portable electronic device 1700 can be used for storing and moving large-volume data. In addition to the functions described above, a function of wireless communication using electromagnetic waves such as infrared rays, a function of receiving television broadcasts, and the like may be included. According to an embodiment of the disclosed invention, a portable electronic device with high reliability and high performance can be provided at a low price.

As described above, the present invention can be applied to and used in a wide range of electronic devices in a variety of fields. Note that this embodiment can be implemented in combination with any of other embodiments and examples as appropriate.

### Example 1

In this example, an experiment was conducted to confirm the effect of heat treatment performed before laser light irradiation. Specifically, Raman spectra of silicon layers each subjected to one of heat treatments under plural conditions or laser light irradiation treatment were observed, and peak wavenumbers (cm⁻¹) thereof and full widths at half maximum (cm⁻¹) of the peaks were compared.

Samples used in this example were each manufactured using an SOI substrate having a structure in which a single crystal silicon layer (60 nm) was provided over a glass substrate with a silicon oxide film (100 nm) that was formed by HCl oxidation interposed therebetween. The treatment performed during manufacturing of each sample is one of heat treatments at respective temperatures (including the case where heat treatment is not performed (hereinafter referred to as “no heat treatment”)) or laser light irradiation treatment. In other words, samples in which single crystal silicon layers were subjected to heat treatments at respective temperatures and a sample in which a single crystal silicon layer was subjected to laser light irradiation treatment without heat treatment were manufactured.

As temperature conditions for the above heat treatments, the following five conditions were adopted: no heat treatment, 550° C., 600° C., 640° C., and 700° C. The length of each heat treatment was 4 hours. The laser light irradiation treatment was performed under conditions (energy density) where the surface planarity of the single crystal silicon layer sufficiently became favorable.

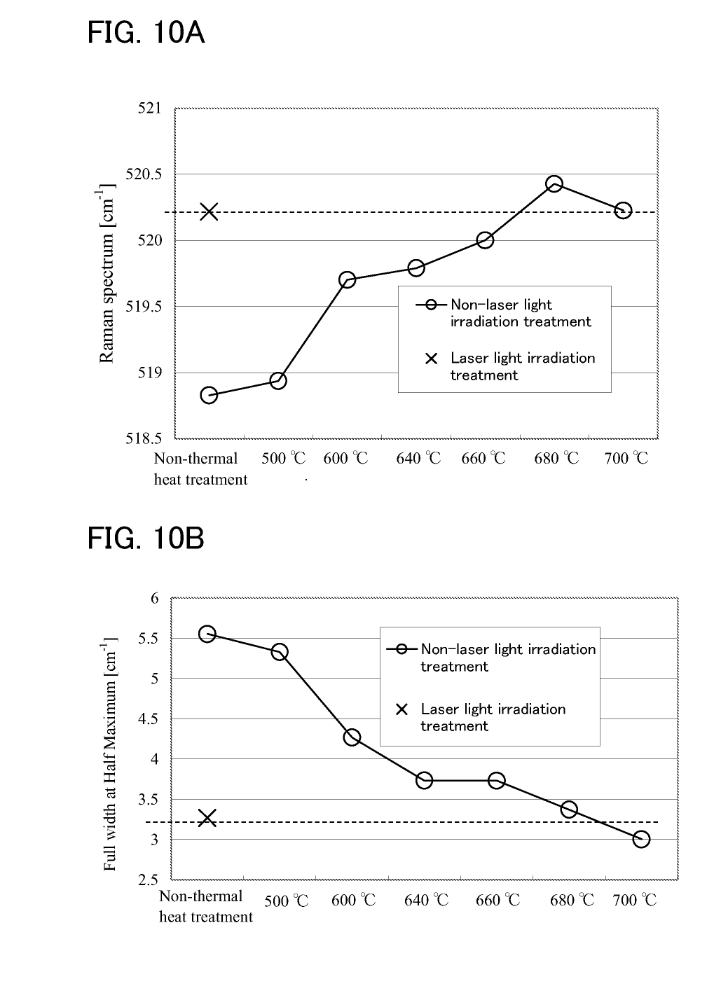

The results of measurements of the samples are illustrated in FIGS. 10A and 10B. FIG. 10A is a graph of peak wavenumbers (cm⁻¹) of the Raman spectra under the respective conditions, and FIG. 10B is a graph of full widths at half maximum (cm⁻¹) of the peaks under the respective conditions.

FIG. 10A shows that the peak wavenumber of the silicon layer irradiated with laser light is about 520.2 cm⁻¹, and this value is very close to that of a single crystal silicon wafer. In other words, defects in a silicon layer are sufficiently reduced by laser light irradiation treatment. On the other hand, in the cases where laser light irradiation is not performed, although the peak wavenumbers obtained through the heat treatments at 660° C. or lower (including no heat treatment) fall short of that obtained through the laser light irradiation treatment, the peak wavenumber (520 cm⁻¹ to 521 cm⁻¹) obtained through the heat treatment at a temperature of 680° C. is substantially equal to that obtained through the laser light irradiation treatment. In other words, by adopting temperature conditions of 680° C. or higher, a sufficient reduction of defects can be expected even if laser light irradiation treatment is not performed.

FIG. 10B shows that the full width at half maximum of the silicon layer irradiated with laser light is about 3.3 cm⁻¹. On the other hand, even if laser light irradiation is not performed, a full width at half maximum which is close to that of the silicon layer subjected to the laser light irradiation treatment is achieved under the temperature conditions of 680° C. or higher. Specifically, the full width at half maximum is 3.5 cm⁻¹ or less under the temperature conditions of 680° C. or higher. Further, the full width at half maximum under the temperature condition of 700° C. is less than that of the silicon layer subjected to the laser light irradiation treatment. Accordingly, by adopting temperature conditions of 680° C. or higher, preferably, 700° C. or higher, a sufficient reduction of defects can be expected even if laser light irradiation treatment is not performed.

As described above, defects in a single crystal semiconductor layer can be sufficiently reduced by heat treatment. Thus, it is highly effective to perform heat treatment before laser light irradiation treatment. In addition, when a single crystal semiconductor layer subjected to heat treatment in the above manner is subjected to laser light irradiation treatment, characteristics of the single crystal semiconductor layer can be further improved.

The structure described in this example can be used in appropriate combination with structures described in other embodiments.

This application is based on Japanese Patent Application serial no. 2008-249992 filed with Japan Patent Office on Sep. 29, 2008, the entire contents of which are hereby incorporated by reference.

What is claimed is:

1. A method for manufacturing an SOI substrate, comprising the steps of:
irradiating a single crystal semiconductor substrate with accelerated ions so that an embrittled region is formed in the single crystal semiconductor substrate;
bonding the single crystal semiconductor substrate and a base substrate to each other with an insulating layer interposed therebetween;
separating the single crystal semiconductor substrate at the embrittled region so that a semiconductor layer is provided over the base substrate;
performing a first heat treatment at a temperature higher than or equal to 700° C. so that a defect in the semiconductor layer is reduced; and
irradiating the semiconductor layer with laser light after the first heat treatment.

2. The method for manufacturing an SOI substrate according to claim 1, further comprising:
etching the semiconductor layer over the base substrate before performing the first heat treatment.

3. The method for manufacturing an SOI substrate according to claim 1, wherein the single crystal semiconductor substrate is separated while a second heat treatment is performed to the single crystal semiconductor substrate.

4. The method for manufacturing an SOI substrate according to claim 1, wherein the laser light irradiation is performed with light having an intensity at which the semiconductor layer is partially melted.

5. The method for manufacturing an SOI substrate according to claim 1, wherein a glass substrate is used as the base substrate.

6. The method for manufacturing an SOI substrate according to claim 1, wherein the first heat treatment is performed for three hours or more.

7. The method for manufacturing an SOI substrate according to claim 1, wherein surface planarity of the semiconductor layer is improved and a defect in the semiconductor layer is reduced by the laser light irradiation.

8. The method for manufacturing an SOI substrate according to claim 1,
wherein a single crystal silicon substrate is used as the single crystal semiconductor substrate, and
wherein the first heat treatment is performed such that a Raman spectrum of the semiconductor layer after the first heat treatment has a wavenumber of 520 cm⁻¹ to 521 cm⁻¹ at a peak and a full width at half maximum of 3.5 cm⁻¹ or less at the peak.

9. A method for manufacturing an SOI substrate, comprising the steps of:
irradiating a single crystal semiconductor substrate with accelerated ions so that an embrittled region is formed in the single crystal semiconductor substrate;
bonding the single crystal semiconductor substrate and a base substrate to each other with an insulating layer interposed therebetween;
separating the single crystal semiconductor substrate at the embrittled region so that a semiconductor layer is provided over the base substrate;
performing a first heat treatment so that a defect in the semiconductor layer is reduced; and
irradiating the semiconductor layer with laser light having an intensity at which the semiconductor layer is partially melted after the first heat treatment.

10. The method for manufacturing an SOI substrate according to claim 9, further comprising:
etching the semiconductor layer over the base substrate before performing the first heat treatment.

11. The method for manufacturing an SOI substrate according to claim 9, wherein the single crystal semiconductor substrate is separated while a second heat treatment is performed to the single crystal semiconductor substrate.

12. The method for manufacturing an SOI substrate according to claim 9, wherein a glass substrate is used as the base substrate.

13. The method for manufacturing an SOI substrate according to claim 9, wherein the first heat treatment is performed for three hours or more.

14. The method for manufacturing an SOI substrate according to claim 9, wherein surface planarity of the semiconductor layer is improved and a defect in the semiconductor layer is reduced by the laser light irradiation.

15. The method for manufacturing an SOI substrate according to claim 9,
wherein a single crystal silicon substrate is used as the single crystal semiconductor substrate, and
wherein the first heat treatment is performed such that a Raman spectrum of the semiconductor layer after the first heat treatment has a wavenumber of 520 cm⁻¹ to 521 cm⁻¹ at a peak and a full width at half maximum of 3.5 cm⁻¹ or less at the peak.

16. The method for manufacturing an SOI substrate according to claim 9, wherein the first heat treatment is performed at a temperature higher than or equal to 680° C. and lower than a strain point of the base substrate.

17. The method for manufacturing an SOI substrate according to claim 9, wherein the first heat treatment is performed at a temperature higher than or equal to 700° C.

18. A method for manufacturing an SOI substrate, comprising the steps of:
forming an oxide film on a surface of a single crystal semiconductor substrate by a thermal oxidation treatment;
irradiating the single crystal semiconductor substrate with accelerated ions so that an embrittled region is formed in the single crystal semiconductor substrate;
bonding the single crystal semiconductor substrate and a base substrate to each other with the oxide film and a nitrogen-containing layer interposed therebetween;
separating the single crystal semiconductor substrate at the embrittled region so that a semiconductor layer is provided over the base substrate with the oxide film and the nitrogen-containing layer interposed therebetween;
performing a first heat treatment at a temperature higher than or equal to 700° C.; and
irradiating the semiconductor layer with laser light after the first heat treatment.

19. The method for manufacturing an SOI substrate according to claim 18, further comprising:
etching the semiconductor layer over the base substrate before performing the first heat treatment.

20. The method for manufacturing an SOI substrate according to claim 18, wherein the single crystal semiconductor substrate is separated while a second heat treatment is performed to the single crystal semiconductor substrate.

21. The method for manufacturing an SOI substrate according to claim 18, wherein the laser light irradiation is performed with light having an intensity at which the semiconductor layer is partially melted.

22. The method for manufacturing an SOI substrate according to claim 18, wherein a glass substrate is used as the base substrate.

23. The method for manufacturing an SOI substrate according to claim 18, wherein the first heat treatment is performed for three hours or more.

24. The method for manufacturing an SOI substrate according to claim 18, wherein surface planarity of the semiconductor layer is improved and a defect in the semiconductor layer is reduced by the laser light irradiation.

25. The method for manufacturing an SOI substrate according to claim 18,
wherein a single crystal silicon substrate is used as the single crystal semiconductor substrate, and
wherein the first heat treatment is performed such that a Raman spectrum of the semiconductor layer after the first heat treatment has a wavenumber of 520 cm⁻¹ to 521 cm⁻¹ at a peak and a full width at half maximum of 3.5 cm⁻¹ or less at the peak.
